(19) United States
(12) Patent Application Publication
(10) Pub. No.: US 2023/0017392 A1
(43) Pub. Date: Jan. 19, 2023

(54) MEASUREMENT MARK, MEASUREMENT LAYOUT, AND MEASUREMENT METHOD

(71) Applicant: CHANGXIN MEMORY TECHNOLOGIES, INC., Hefei City (CN)

(72) Inventor: Shaowen Qiu, Hefei City (CN)

(21) Appl. No.: 17/454,159

(22) Filed: Nov. 9, 2021

Related U.S. Application Data
(63) Continuation of application No. PCT/CN2021/110720, filed on Aug. 5, 2021.

(30) Foreign Application Priority Data
Jul. 15, 2021 (CN) 202110799419.8

(51) Int. Cl. H01L 23/544; G03F 7/20

(52) U.S. Cl. CPC H01L 23/544; G03F 7/70625; G03F 7/70633; G03F 7/70683

(57) ABSTRACT

The present disclosure provides a measurement mark, a measurement layout, and a semiconductor structure measurement method. A measurement mark includes a first pattern, a second pattern, and a third pattern, the first pattern includes multiple first marks extending in a first direction and arranged in parallel at intervals in a second direction, the second pattern includes multiple second marks arranged at intervals in a staggered manner, and the third pattern includes multiple third marks arranged at intervals in a staggered manner; in projection of the measurement mark on the substrate, projection of the second mark separates projection of the first mark in the first direction; projection of the second pattern does not overlap with projection of the third pattern, and there is an offset distance between the projection of the third pattern and the projection of the second pattern in a third direction.

### CROSS-REFERENCE TO RELATED APPLICATIONS

This is a continuation of International Patent Application No. PCT/CN2021/110720, filed on Aug. 5, 2021, which claims the priority to Chinese Patent Application No. 202110799419.8, titled “MEASUREMENT MARK, MEASUREMENT LAYOUT, AND MEASUREMENT METHOD” and filed on Jul. 15, 2021. The entire contents of International Patent Application No. PCT/CN2021/110720 and Chinese Patent Application No. 202110799419.8 are incorporated herein by reference.

### TECHNICAL FIELD

The present disclosure relates to, but is not limited to, a measurement mark, a measurement layout, and a semiconductor structure measurement method.

### BACKGROUND

A semiconductor structure usually includes multiple patterned material layers, and each current layer has to be aligned with a previous layer within a strict tolerance. An overlay registration error between the current layer and the previous layer of the semiconductor structure is referred to as an overlay error. The overlay error is used to describe a deviation between a pattern on the current layer and a pattern on the previous layer along a surface of a wafer and a distribution status of this deviation on the surface of the wafer. The overlay error is a key indicator for checking the quality of a photolithography process.

### SUMMARY

An overview of the subject matter detailed in the present disclosure is provided below, which is not intended to limit the protection scope of the claims.

Embodiments of the present disclosure provide a measurement mark for an overlay error, a measurement layout, and a semiconductor structure measurement method.

According to some embodiments, a first aspect of the present disclosure provides a measurement mark, applied to a semiconductor structure. The semiconductor structure includes a substrate, the measurement mark includes a first pattern, a second pattern, and a third pattern, the first pattern includes multiple first marks extending in a first direction and arranged in parallel at intervals in a second direction, the second pattern includes multiple second marks arranged at intervals in a staggered manner, and the third pattern includes multiple third marks arranged at intervals in a staggered manner;

in projection of the measurement mark on the substrate,

projection of the second mark separates projection of the first mark in the first direction; projection of the second pattern does not overlap with projection of the third pattern, and there is an offset distance between the projection of the third pattern and the projection of the second pattern in a third direction; and

the first direction is perpendicular to the second direction, and the third direction is different from the first direction.

According to some embodiments, a second aspect of the present disclosure provides a measurement layout for an overlay error, including multiple measurement marks according to any implementation of the first aspect. The multiple measurement marks are arranged based on offset distances of the measurement marks, and at least some of the offset distances of the multiple measurement marks are different.

According to some embodiments, a third aspect of the present disclosure provides a semiconductor structure. The semiconductor structure includes the measurement layout according to any implementation of the second aspect.

According to some embodiments, a fourth aspect of the present disclosure provides a measurement method for a semiconductor structure. The measurement method includes: establishing a correspondence between an offset distance and asymmetrical optical signal by using the measurement layout according to any implementation of the second aspect and asymmetrical optical signal, where the asymmetrical optical signal is generated by measurement marks with different offset distances in the measurement layout under zero-order diffracted light; and obtaining an overlay error of a target semiconductor structure based on the correspondence and asymmetrical optical signal of the target semiconductor structure under the zero-order diffracted light.

### BRIEF DESCRIPTION OF THE DRAWINGS

The accompanying drawings incorporated into the specification and constituting a part of the specification illustrate embodiments of the present disclosure, and are used to explain the principles of the embodiments of the present disclosure together with the description. In these accompanying drawings, similar reference numerals are used to represent similar elements. The accompanying drawings in the following description show merely some rather than all of the embodiments of the present disclosure. Persons skilled in the art may derive other accompanying drawings from these accompanying drawings without creative efforts.

FIG. 1 is a schematic diagram of a previous layer and a current layer of a semiconductor structure according to an exemplary embodiment;

FIG. 2 is a schematic diagram of a semiconductor structure according to an exemplary embodiment;

FIG. 3 is a schematic diagram of a measurement mark according to an exemplary embodiment;

FIG. 4 is a schematic diagram of a first pattern according to an exemplary embodiment;

FIG. 5 is a schematic diagram of a second pattern according to an exemplary embodiment;

FIG. 6 is a schematic diagram of a third pattern according to an exemplary embodiment;

FIG. 7 is a schematic diagram of a second mark layer according to an exemplary embodiment;

FIG. 8 is a schematic diagram of a second mark layer according to an exemplary embodiment;

FIG. 9 is a schematic diagram of a second mark layer according to an exemplary embodiment;

FIG. 10 is a schematic diagram of a second mark layer according to an exemplary embodiment;

FIG. 11 is a schematic diagram of a first mark layer according to an exemplary embodiment;

FIG. 12 is a schematic diagram of a first mark layer according to an exemplary embodiment;

FIG. 13 is a schematic diagram of a measurement layout according to an exemplary embodiment;

FIG. 14 is a schematic diagram of a measurement layout according to an exemplary embodiment; and

FIG. 15 is a schematic diagram of a measurement layout according to an exemplary embodiment.

### DETAILED DESCRIPTION

The following clearly and completely describes the technical solutions in the embodiments of the present disclosure with reference to the accompanying drawings in the embodiments of the present disclosure. Apparently, the described embodiments are merely a part rather than all of the embodiments of the present disclosure. All other embodiments obtained by persons skilled in the art based on the embodiments in the present disclosure without creative efforts shall fall within the protection scope of the present disclosure. It should be noted that the embodiments in the present disclosure and features in the embodiments may be combined with each other in a non-conflicting manner.

Overlay error detection is usually divided into after development inspection (ADI) and after etching inspection (AEI).

The after development inspection is critical dimension (CD) measurement after development. The after development inspection is usually used to detect performance indicators of an exposure machine and a developing machine. After the exposure and development are completed, a generated pattern is qualitatively inspected by using an ADI machine to determine whether the pattern is normal. Because transmitted light measurement cannot be conducted, the ADI is usually implemented through measurement by means of an electron beam, a scanning electron microscope, or the like.

The after etching inspection is CD measurement after etching. Full inspection or sampling inspection is conducted on products before and after a photoresist is removed in an etching process.

Usually, an overlay error can be measured by using an image based overlay (IBO) measurement technology, a scanning electron microscope (SEM), and a new diffraction measurement technology (in device metrology (IDM), which is also referred to as in die measurement).

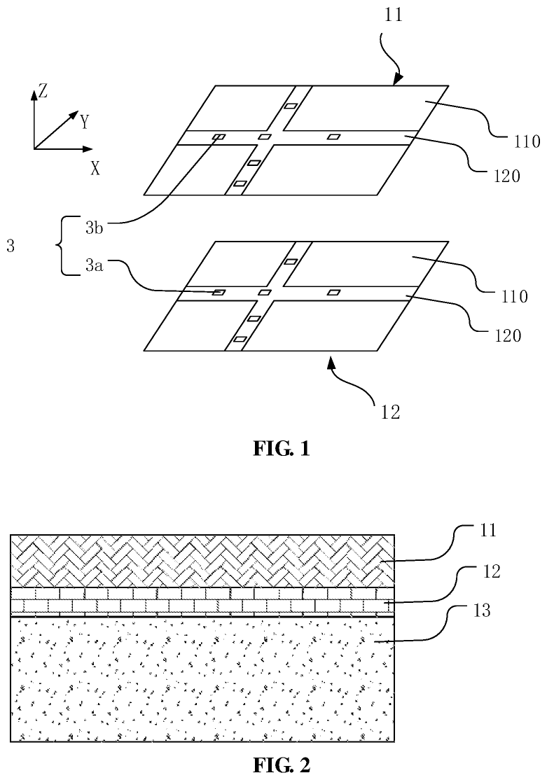

The SEM is usually used for after development inspection. For an opening layer with openings in a semiconductor structure, the SEM cannot accurately measure overlay errors in a horizontal direction (refer to an X direction in FIG. 1) and a vertical direction (refer to a Y direction in FIG. 1). The IBO is also usually used for after development inspection, and relies on a measurement mark (Mark) for measurement. For the opening layer with openings in the semiconductor structure, an overlay error cannot be accurately measured either. The IDM is usually used for after etching inspection without need to set a specific measurement mark. Instead, an original pattern of the semiconductor structure is used to measure an overlay error in the IDM. However, the IDM relies on asymmetry of light intensity distribution of zero-order diffracted light. For the opening layer with openings in the semiconductor structure, because light intensity distribution of zero-order diffracted light having passed through original patterns on a current layer and a previous layer, it is also impossible to implement overlay error measurement.

The embodiments of the present disclosure provide a measurement mark for an overlay error. The measurement mark is applied to a semiconductor structure. A known offset direction and offset distance are set for the measurement mark to measure an unknown overlay error. The measurement mark has a wider application range, can be used to measure an overlay error between any two layers of the semiconductor structure, and improves the accuracy and efficiency of overlay error measurement to a certain extent, thereby improving a product yield.

Referring to FIG. 1 to FIG. 6, an exemplary embodiment of the present disclosure provides a measurement mark 2. The measurement mark 2 is applied to a semiconductor structure, and the semiconductor structure includes a substrate 13. The measurement mark 2 includes a first pattern 100, a second pattern 200, and a third pattern 300.

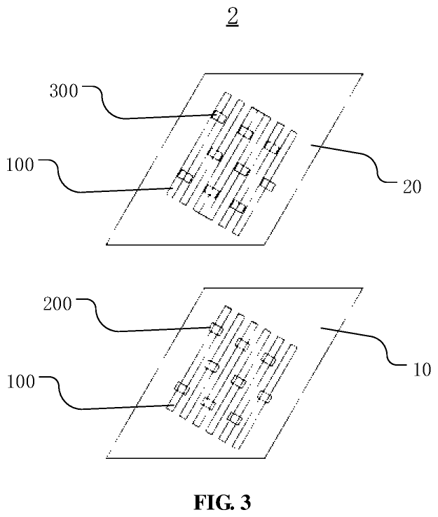

It should be noted that, referring to FIG. 3, the measurement mark 2 may include two mark layers that are respectively denoted as a first mark layer 10 and a second mark layer 20. The first mark layer 10 includes the first pattern 100 and the second pattern 200, and the second mark layer 20 includes the first pattern 100 and the third pattern 300.

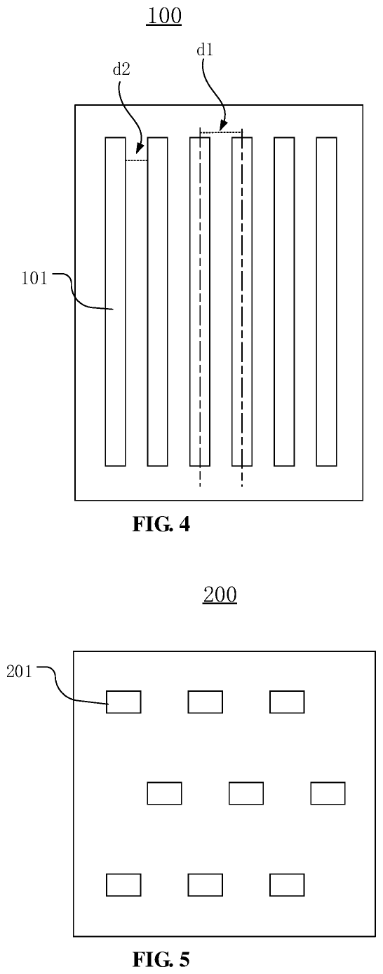

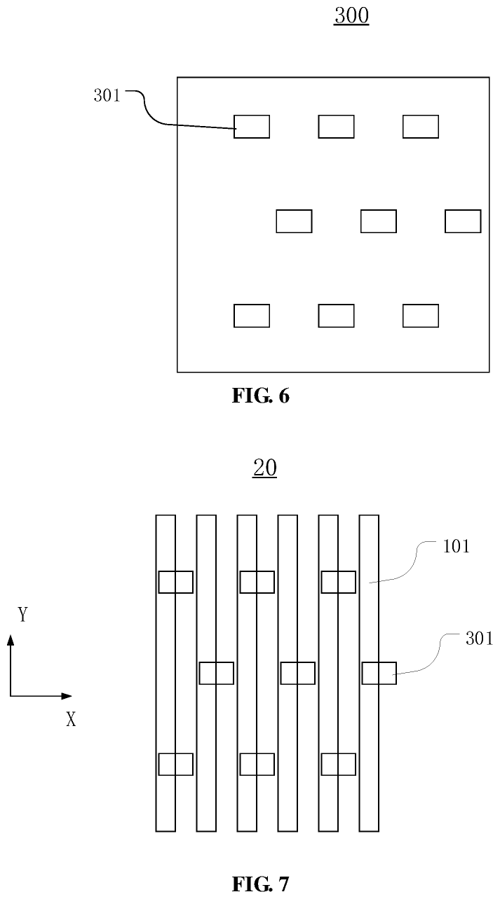

Referring to FIG. 4, the first pattern 100 includes multiple first marks 101 extending in a first direction and arranged in parallel at intervals in a second direction. Referring to FIG. 5, the second pattern 200 includes multiple second marks 201 arranged at intervals in a staggered manner Referring to FIG. 6, the third pattern 300 includes multiple third marks 301 arranged at intervals in a staggered manner.

In other words, the first mark layer 10 of the measurement mark 2 includes the multiple first marks 101 and the multiple second marks 201, and the second mark layer 20 includes the multiple first marks 101 and the multiple third marks 301.

In projection of the measurement mark 2 on the substrate 13 (refer to FIG. 2), projection of the first mark 101 of the first mark layer 10 coincides with projection of the first mark 101 of the second mark layer 20, or in other words, the first mark 101 of the first mark layer 10 and the second mark 201 of the second mark layer 20 are arranged in a same form.

In addition, in the projection of the measurement mark 2 on the substrate 13, projection of the second mark 201 separates projection of the first mark 101 in the first direction, projection of the second pattern 200 does not overlap with projection of the third pattern 300, and there is an offset distance between the projection of the third pattern 300 and the projection of the second pattern 200 in a third direction. The first direction is perpendicular to the second direction, and the third direction is different from the first direction, to ensure asymmetry of the measurement mark 2.

In the first pattern 100 of the measurement mark 2, there is a same spacing between adjacent first marks 101 in the second direction. In other words, the first marks 101 of the first pattern 100 are arranged regularly to facilitate arrangement of the first marks 101.

The spacing between adjacent first marks 101 may be denoted as a first spacing. The first spacing may be a center distance between adjacent first marks 101 (refer to d1 shown in FIG. 4), or may be a spacing distance (refer to d2 shown in FIG. 4) between adjacent first marks 101. An offset distance of the measurement mark 2 may be 0.25 times to 0.5 times the first spacing.

In addition, the second direction and the third direction may be the same, or may be different.

### Example 1

Referring to FIG. 7 and FIG. 11, the first direction is a vertical direction. For the first direction, refer to a direction shown by Y in FIG. 7. The second direction is a horizontal direction. The third direction is the same as the second direction and is also the horizontal direction. For the second direction and the third direction, refer to a direction shown by X in FIG. 7. The first mark 101 is a long strip mark, and the second mark 201 is a rectangular hole mark. The third mark 301 has a same structure as the second mark 201 and is also a rectangular hole mark. The offset distance of the measurement mark 2 may be 0.25 times the first spacing.

For the first mark layer 10, refer to FIG. 11. For the second mark layer 20, refer to FIG. 7.

### Example 2

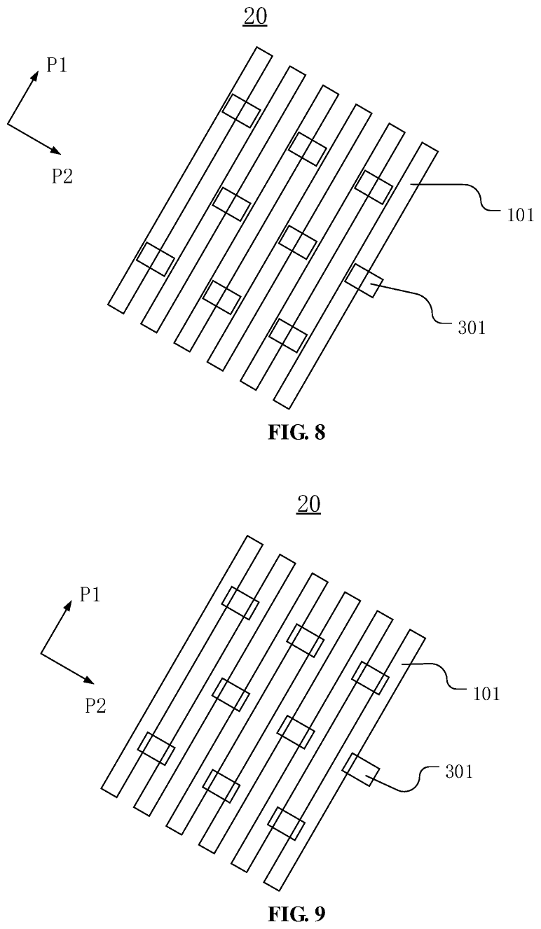

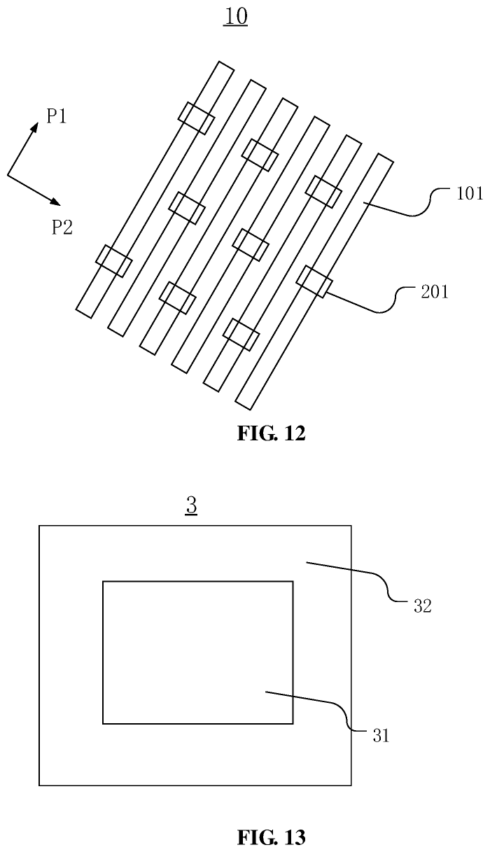

Referring to FIG. 8 and FIG. 12, there is an included angle of 30° between the first direction and a vertical direction. For the first direction, refer to a direction shown by P1 in FIG. 8. The second direction is perpendicular to the first direction, and the third direction is the same as the second direction. For the second direction and the third direction, refer to a direction shown by P2 in FIG. 8. The first mark 101 is a long strip mark, and the second mark 201 is a rectangular hole mark. The third mark 301 has a same structure as the second mark 201 and is also a rectangular hole mark. The offset distance of the measurement mark 2 may be 0.25 times the first spacing.

For the first mark layer 10, refer to FIG. 12. For the second mark layer 20, refer to FIG. 8.

### Example 3

Referring to FIG. 9 and FIG. 12, there is an included angle of 30° between the first direction and a vertical direction. For the first direction, refer to a direction shown by P1 in FIG. 9. The second direction is perpendicular to the first direction, and the third direction is the same as the second direction. For the second direction and the third direction, refer to a direction shown by P2 in FIG. 9. The first mark 101 is a long strip mark, and the second mark 201 is a rectangular hole mark. The third mark 301 has a same structure as the second mark 201 and is also a rectangular hole mark. The offset distance of the measurement mark 2 may be 0.5 times the first spacing.

The first pattern 100 is shown in the figure, the second pattern 200 is shown in the figure, and the third pattern 300 is shown in the figure. For the first mark layer 10, refer to FIG. 12. For the second mark layer 20, refer to FIG. 9.

### Example 4

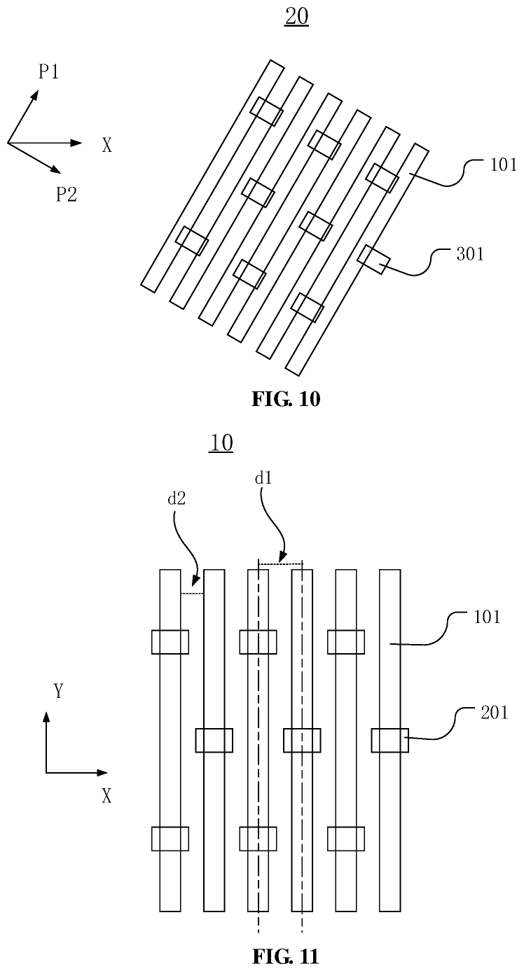

Referring to FIG. 10 and FIG. 12, there is an included angle of 30° between the first direction and a vertical direction. For the first direction, refer to a direction shown by P1 in FIG. 10. The second direction is perpendicular to the first direction. For the second direction, refer to a direction shown by P2 in FIG. 10. The third direction is a horizontal direction, and is different from the second direction. For the third direction, refer to a direction shown by X in FIG. 10. The first mark 101 is a long strip mark, and the second mark 201 is a rectangular hole mark. The third mark 301 has a same structure as the second mark 201 and is also a rectangular hole mark. The offset distance of the measurement mark 2 may be 0.5 times the first spacing.

For the first mark layer 10, refer to FIG. 12. For the second mark layer 20, refer to FIG. 10.

It should be noted that, in addition to the directions in Example 1 to Example 4, the third direction may be a direction opposite to each of the directions in Example 1 to Example 4 or another direction different from the first direction.

The measurement mark 2 is mainly used for after etching inspection. Light intensity distribution of zero-order diffracted light generated after measurement light passes through the measurement mark 2 is asymmetrical. Therefore, an overlay error between the first mark layer 10 (for example, a previous layer 12) and the second mark layer 20 (for example, a current layer 11) of the measurement mark 2 may be calculated based on the asymmetry of light intensity distribution of the zero-order diffracted light, to obtain an overlay error between the current layer 11 and the previous layer 12 of the semiconductor structure. In this way, the overlay error is accurately measured. The measurement mark 2 may be used to measure an overlay error between any two layers of the semiconductor structure.

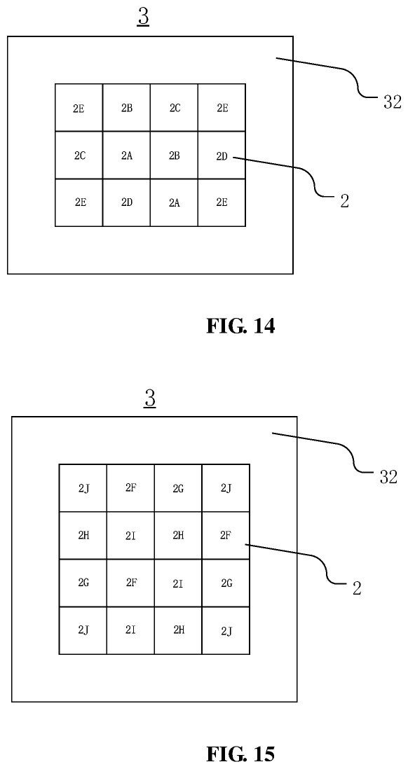

Referring to FIG. 14 and FIG. 15, an exemplary embodiment of the present disclosure provides a measurement layout 3 for an overlay error. The measurement layout 3 may include multiple measurement marks 2 for an overlay error, and the multiple measurement marks 2 together form a measurement portion 31 of the measurement layout 3.

It should be noted that, referring to FIG. 1, the measurement layout 3 includes a first layout layer 3a on the current layer of the semiconductor structure and a second layout layer 3b on the previous layer of the semiconductor structure. The first layout layer 3a includes first mark layers 10 of the multiple measurement marks 2, and the second layout layer 3b includes second mark layers 20 of the multiple measurement marks 2.

At least some of offset distances of the multiple measurement marks 2 are different, and the multiple measurement marks 2 are arranged based on the offset distances of the measurement marks 2.

That the multiple measurement marks 2 in the measurement layout 3 are arranged based on the offset distances of the measurement marks 2 may include: The multiple measurement marks 2 are asymmetrically distributed based on the offset distances of the measurement marks 2. This increases the asymmetry of light intensity distribution of the zero-order diffracted light, such that overlay error measurement is completed more reliably.

In the measurement layout 3, the multiple measurement marks 2 are arranged in linear distribution or normal distribution based on the offset distances of the measurement marks 2.

In other words, in the measurement layout 3, each measurement mark 2 corresponds to one offset distance, and multiple different offset distances are in linear distribution or normal distribution.

For example, the first spacing is a nanometers, and multiple different offset distances are 0.3a−5 nanometers, 0.3a−2.5 nanometers, 0.3a nanometers, 0.3a+2.5 nanometers, and 0.3a+5 nanometers.

There is a same difference between some adjacent offset distances of the measurement marks 2, and the difference is less than or equal to 6 nanometers.

In other words, offset distances of some of the multiple measurement marks 2 are different, and in these different offset distances, there is a same difference between adjacent offset distances. To be specific, these different offset distances are arranged at an equal difference, and a maximum value of the difference may be 6 nanometers.

For example, when the first spacing is a nanometers, and multiple different offset distances are 0.3a−5 nanometers, 0.3a−2.5 nanometers, 0.3a nanometers, 0.3a+2.5 nanometers, and 0.3a+5 nanometers, differences between adjacent offset distances are all 2.5 nanometers.

Referring to FIG. 13 to FIG. 15, an exemplary embodiment of the present disclosure provides a measurement layout 3 for an overlay error. The measurement layout 3 includes N×M measurement marks 2, and the N×M measurement marks 2 define an N×M matrix structure, to facilitate arrangement of the multiple measurement marks 2. M and N are both positive integers greater than or equal to 1.

The measurement layout 3 may further include a protection portion 32, and the protection portion 32 is located at the periphery of the matrix structure. The protection portion 32 is not involved in the measurement, but is only used to protect the matrix structure to avoid impact on the measurement caused when the matrix structure is damaged due to a processing error.

### Example 1

Referring to FIG. 13 to FIG. 14, a measurement portion 31 of the measurement layout 3 may include 4×3=12 measurement marks 2. A first spacing between the measurement marks 2 is a nanometers, the 12 measurement marks 2 form a 4×3 matrix structure, and a protection portion 32 is arranged outside the matrix structure.

Offset distances of the 12 measurement marks 2 include 0.3a−5 nanometers, 0.3a−2.5 nanometers, 0.3a nanometers, 0.3a+2.5 nanometers, and 0.3a+5 nanometers. The 0.3a−5 nanometers correspond to two measurement marks 2A, the 0.3a−2.5 nanometers correspond to two measurement marks 2B, the 0.3a+2.5 nanometers correspond to two measurement marks 2C, the 0.3a+5 nanometers correspond to two measurement marks 2D, and the 0.3a nanometers correspond to four measurement marks 2E.

The two measurement marks 2A, the two measurement marks 2B, the two measurement marks 2C, the two measurement marks 2D, and two measurement marks 2E form a reference group. The other two measurement marks 2E form a measurement group, and the measurement marks 2E are respectively located at two diagonal corners of the matrix structure.

During measurement of an overlay error by using the measurement layout 3, asymmetrical optical signal of zero-order diffracted light are generated by each measurement mark 2. A correspondence between an offset distance and asymmetrical optical signal is first determined based on multiple asymmetrical optical signal and offset distances corresponding to the reference group, and then an overlay error between the first mark layer and the second mark layer, that is, an overlay error between two layers of the semiconductor structure, is obtained based on asymmetrical optical signal corresponding to the measurement group and the correspondence.

### Example 2

Referring to FIG. 13 and FIG. 15, a measurement portion 31 of the measurement layout 3 may include 4×4=16 measurement marks 2. A first spacing between the measurement marks 2 is a nanometers, the 16 measurement marks 2 define a 4×4 matrix structure, and a protection portion 32 is arranged outside the matrix structure.

Offset distances of the 16 measurement marks 2 include 0.5a−6 nanometers, 0.5a−3 nanometers, 0.5a nanometers, 0.5a+3 nanometers, and 0.5a+6 nanometers. The 0.5a−3 nanometers correspond to three measurement marks 2F, the 0.5a nanometers correspond to three measurement marks 2G, the 0.5a+3 nanometers correspond to three measurement marks 2H, the 0.5a+6 nanometers correspond to three measurement marks 2I, and the 0.5a−6 nanometers correspond to four measurement marks 2J.

The three measurement marks 2F, the three measurement marks 2G, the three measurement marks 2H, and the three measurement marks 2I form a reference group. The four measurement marks 2J form a measurement group, and the four measurement marks 2J are respectively located at four top corners of the matrix structure.

It should be noted that during measurement of an overlay error by using the measurement layout 3, measurement light irradiates a position at which each measurement mark 2 in the measurement layout 3 is located, and the measurement light forms multi-order diffracted light after passing through the second mark layer and the first mark layer. Zero-order diffracted light is collected from the multi-order diffracted light, and optical signal (that is, signal indicating light intensity distribution) of the zero-order diffracted light are formed. The optical signal are asymmetrical optical signal. Then, an overlay error between the first mark layer and the second mark layer is determined based on the asymmetry of the optical signal, to determine an overlay error between the previous layer and the current layer of the semiconductor structure. In this way, the overlay error between the current layer and the previous layer is measured.

In addition, referring to FIG. 1, FIG. 2, FIG. 3, and FIG. 13 to FIG. 15, zero-order diffracted light is generated after measurement light passes through the second mark layer 20 and the first mark layer 10 of the measurement mark 2, and light intensity distribution of the zero-order diffracted light is asymmetrical. Therefore, an overlay error between any two layers may be measured by using the measurement layout 3 provided with the measurement marks 2, without being limited by an image on each layer of active area 120. This expands an application range of overlay error measurement based on diffraction.

The current layer 11 may be an opening layer of the semiconductor structure, or in other words, the second mark layer 20 may be located on the opening layer of the semiconductor structure. The measurement of an overlay error between the opening layer and other layers has been completed.

It should be noted that the current layer 11 and the previous layer 12 may be two adjacent layers (as shown in FIG. 2), or two nonadjacent layers (not shown in the figure). In other words, there may be no other layer between the current layer 11 and the previous layer 12, or there may be another layer between the current layer 11 and the previous layer 12. The previous layer 12 may be in direct contact with the substrate 13 (as shown in FIG. 2). Alternatively, another layer (not shown in the figure) may be arranged between the previous layer 12 and the substrate 13.

Referring to FIG. 1 to FIG. 3 and FIG. 13 to FIG. 15, an exemplary embodiment of the present disclosure provides a semiconductor structure. The semiconductor structure includes the foregoing measurement layout 3. After the semiconductor structure is etched, measurement light may enter from a current layer 11 of the semiconductor structure, and light intensity distribution of zero-order diffracted light generated after the measurement light passes through the measurement layout 3 is asymmetrical, or in other words, asymmetrical optical signal of zero-order diffracted light is generated by each measurement mark 2. A correspondence between an offset distance and asymmetrical optical signal is first determined based on multiple asymmetrical optical signals and offset distances corresponding to a reference group of the measurement layout 3, and then an overlay error between a first mark layer 10 and a second mark layer 20, that is, an overlay error between two layers of the semiconductor structure, is obtained based on asymmetrical optical signal corresponding to a measurement group and the correspondence.

The semiconductor structure may include multiple measurement layouts 3, and the multiple measurement layouts 3 are at different positions of a scribe line region 110 of the semiconductor structure. The measurement layout 3 is located in the scribe line region 110 of the semiconductor structure, to avoid damage to an active area 120 of the semiconductor structure. Therefore, an overlay error between different layers may be measured by using the measurement layout 3 in the scribe line region 110, to further obtain an overlay error between patterns on different layers of active areas 120. This improves a product yield of semiconductor structures.

In addition, in the semiconductor structure, overlay errors at different positions in the scribe line region 110 are measured to determine an overlay error between active areas 120 of the semiconductor structure more comprehensively and reliably. In this way, an overlay error of the entire semiconductor structure is determined more accurately, thereby improving the measurement accuracy.

It should be noted that the measurement layout 3 specially used for overlay error measurement is arranged in the semiconductor structure, and the measurement layout 3 is arranged in the scribe line region 110. Therefore, even if the current layer 11 or a previous layer 12 of the semiconductor structure is an opening layer, or both the current layer 11 and the previous layer 12 are opening layers, measurement of an overlay error between the current layer 11 and the previous layer 12 is not affected.

For example, the current layer 11 is provided with multiple openings, or in other words, the current layer 11 is an opening layer. By setting the foregoing measurement layout 3, an overlay error between a pattern in an active area 120 of the current layer 11 and a pattern in an active area 120 of the previous layer 12 can still be measured accurately. In this way, the overlay error between the current layer 11 and the previous layer 12 is measured accurately, thereby improving a product yield.

An exemplary embodiment of the present disclosure provides a measurement method for a semiconductor structure. The measurement method includes: establishing a correspondence between an offset distance and asymmetrical optical signal by using the foregoing measurement layout 3 and asymmetrical optical signal, where the asymmetrical optical signal is generated by measurement marks 2 with different offset distances in the measurement layout 3 under zero-order diffracted light; and obtaining an overlay error of a target semiconductor structure based on the correspondence and asymmetrical optical signal of the target semiconductor structure under the zero-order diffracted light.

The target semiconductor structure is denoted as a semiconductor structure for which an overlay error needs to be measured. The semiconductor structure is the semiconductor structure provided with the measurement layout 3 in the foregoing exemplary embodiments.

The measurement method is different from conventional IBO and IDM, but is a measurement method that combines advantages of conventional IBO and IDM. In the measurement method, the measurement layout 3 is arranged in the semiconductor structure in advance, the measurement layout 3 includes multiple measurement marks 2, and overlay error measurement is implemented based on light intensity distribution of zero-order diffracted light. In this way, measurement of an overlay error between any two layers of the semiconductor structure. In other words, the measurement method can accurately measure an overlay error between an opening layer and another layer, thereby better improving a product yield.

The measurement layout 3 may be located in a scribe line region 110 of the semiconductor structure. In other words, the measurement method is applied to the foregoing semiconductor structure in which the measurement layout 3 is arranged in the scribe line region 110. The measurement layout 3 can be arranged in the scribe line region 110 to avoid mutual influence between the measurement layout 3 and a pattern of an active area 120. This not only can ensure performance of the semiconductor structure, but also can better ensure accurate arrangement of the measurement layout 3, thereby further improving the measurement accuracy and increasing applicable measurement scenarios.

The measurement layout 3 may include a reference group and a measurement group. During measurement of the semiconductor structure by using the measurement layout 3, asymmetrical optical signal of zero-order diffracted light is generated through each measurement mark 2 in the measurement layout 3. A correspondence between an offset distance and asymmetrical optical signal is first determined based on multiple asymmetrical optical signals and offset distances corresponding to the reference group, and then an overlay error between a first mark layer 10 and a second mark layer 20, that is, an overlay error between two layers of the semiconductor structure, is obtained based on asymmetrical optical signal corresponding to the measurement group and the correspondence.

In the measurement method, an offset distance and an offset direction of each measurement mark 2 are known, and the known offset direction and offset distance are set to measure an unknown overlay error. The measurement method has a wider application range, and can be used to measure an overlay error between any two layers of the semiconductor structure. In addition, the measurement accuracy is improved, fewer parameters and information are required, and the measurement and calculation efficiency can further be improved.

In the measurement layout, asymmetry of the measurement layout is increased by using different offset distances of different measurement marks, to better obtain the asymmetrical optical signal of the zero-order diffracted light, and establish the correspondence between a known offset distance and asymmetrical optical signal, so as to obtain the overlay error of the target semiconductor structure by detecting the asymmetrical optical signal of the target semiconductor structure.

It should be noted that the foregoing measurement method may be implemented by a measurement device (not shown in the figure). The measurement device may be provided as a server. The measurement device may include a processor, and one or more processors may be set as required. The measurement device may further include a memory configured to store executable instructions of the processor, for example, an application program. One or more memories may be set as required. The memory may store one or more application programs. The processor is configured to execute the instructions to implement the foregoing measurement method.

For example, the processor is configured to conduct the following steps: establishing a correspondence between an offset distance and asymmetrical optical signal by using a measurement layout and asymmetrical optical signal generated by measurement marks with different offset distances in the measurement layout under zero-order diffracted light; and obtaining an overlay error of a target semiconductor structure based on the correspondence and asymmetrical optical signal of the target semiconductor structure under the zero-order diffracted light.

The memory may be a non-transitory computer-readable storage medium (not shown in the figure). When the instructions in the storage medium are executed by the processor of the measurement device, the measurement device is enabled to implement the foregoing measurement method.

For example, when the instructions in the storage medium are executed by the processor of the measurement device, the measurement device is enabled to conduct the following steps: establishing a correspondence between an offset distance and asymmetrical optical signal by using a measurement layout and asymmetrical optical signal generated by measurement marks with different offset distances in the measurement layout under zero-order diffracted light; and obtaining an overlay error of a target semiconductor structure based on the correspondence and asymmetrical optical signal of the target semiconductor structure under the zero-order diffracted light.

Each embodiment or implementation in the specification is described in a progressive manner Each embodiment focuses on the difference from other embodiments, and for the same and similar parts between the embodiments, mutual reference may be made.

In the descriptions of this specification, a description with reference to the term “embodiment”, “exemplary embodiment”, “some implementations”, “an exemplary implementation”, “an example”, and the like means that a specific feature, structure, material, or characteristic described in combination with the implementation(s) or example(s) is included in at least one implementation or example of the present disclosure.

In this specification, the schematic expression of the above terms does not necessarily refer to the same implementation or example. Moreover, the described specific feature, structure, material or characteristic may be combined in an appropriate manner in any one or more implementations or examples.

It should be understood that, in the descriptions of the present disclosure, orientations or position relationships indicated by terms such as “center”, “upper”, “lower”, “left”, “right”, “vertical”, “horizontal”, “inside”, and “outside” are orientations or position relationships based on illustrations in the accompanying drawings. The terms are merely intended to facilitate and simplify the descriptions of the present disclosure, but are not intended to indicate or imply that an indicated apparatus or element needs to have a particular orientation and needs to be constructed and operated in a particular orientation, and therefore cannot be construed as a limitation on the present disclosure.

It can be understood that the terms “first”, “second”, and the like used in the present disclosure can be used to describe various structures in the present disclosure, but these structures are not limited by these terms. These terms are only used to distinguish a first structure from another structure.

In one or more drawings, same components are represented by similar reference numerals. For clarity, various parts in the accompanying drawings are not drawn to scale. In addition, some well-known parts may not be shown. For brevity, a structure obtained after several steps are implemented may be described in one figure. In the following, many specific details in the present disclosure are described, for example, a structure, a material, and a dimension of a device, and a processing process and a technology for the device, to understand the present disclosure more clearly. However, as persons skilled in the art can understand, the present disclosure may not be implemented according to these specific details.

Finally, it should be noted that the above embodiments are merely intended to describe the technical solutions of the present disclosure, rather than to limit the present disclosure. Although the present disclosure is described in detail with reference to the above embodiments, persons skilled in the art should understand that they may still make modifications to the technical solutions described in the above embodiments or make equivalent replacements to some or all technical features thereof, without departing from the scope of the technical solutions in the embodiments of the present disclosure.

1. A measurement mark, applied to a semiconductor structure, wherein the semiconductor structure comprises a substrate, the measurement mark comprises a first pattern, a second pattern, and a third pattern, the first pattern comprises multiple first marks extending in a first direction and arranged in parallel at intervals in a second direction, the second pattern comprises multiple second marks arranged at intervals in a staggered manner, and the third pattern comprises multiple third marks arranged at intervals in a staggered manner;
in projection of the measurement mark on the substrate,
projection of the second mark separates projection of the first mark in the first direction; projection of the second pattern does not overlap with projection of the third pattern, and there is an offset distance between the projection of the third pattern and the projection of the second pattern in a third direction; and
the first direction is perpendicular to the second direction, and the third direction is different from the first direction.

2. The measurement mark according to claim 1, wherein in the first pattern, there is a same spacing between adjacent first marks in the second direction.

3. The measurement mark according to claim 2, wherein a spacing between adjacent first marks is a first spacing, and an offset distance of the measurement mark is 0.25 times to 0.5 times the first spacing.

4. The measurement mark according to claim 1, wherein the second direction is the same as the third direction.

5. A measurement layout for an overlay error, comprising multiple measurement marks according to claim 1 for an overlay error, wherein the multiple measurement marks are arranged based on offset distances of the measurement marks, and at least some of the offset distances of the multiple measurement marks are different.

6. The measurement layout according to claim 5, wherein in the measurement layout, the multiple measurement marks are asymmetrically distributed based on the offset distances of the measurement marks.

7. The measurement layout according to claim 6, wherein in the measurement layout, the multiple measurement marks are arranged in linear distribution or normal distribution based on the offset distances of the measurement marks.

8. The measurement layout according to claim 7, wherein in some measurement marks, there is a same difference between adjacent offset distances of the measurement marks.

9. The measurement layout according to claim 6, wherein in some measurement marks, a difference between adjacent offset distances of the measurement marks is less than or equal to 6 nanometers.

10. The measurement layout according to claim 5, wherein the measurement layout comprises N×M measurement marks, and the N×M measurement marks define an N×M matrix structure.

11. The measurement layout according to claim 10, wherein the measurement layout further comprises a protection portion, and the protection portion is located at a periphery of the N×M matrix structure.

12. A semiconductor structure, wherein the semiconductor structure comprises the measurement layout according to claim 5.

13. The semiconductor structure according to claim 12, wherein the semiconductor structure comprises multiple measurement layouts, and the multiple measurement layouts are located at different positions of a scribe line region of the semiconductor structure.

14. A measurement method for a semiconductor structure, comprising:
establishing a correspondence between an offset distance and asymmetrical optical signal by using the measurement layout according to claim 5 and asymmetrical optical signal, wherein the asymmetrical optical signal is generated by measurement marks with different offset distances in the measurement layout under zero-order diffracted light; and
obtaining an overlay error of a target semiconductor structure based on the correspondence and asymmetrical optical signal of the target semiconductor structure under the zero-order diffracted light.
